(19) United States
(12) Patent Application Publication
(10) Pub. No.: US 2026/0287620 A1
(43) Pub. Date: Sep. 24, 2026

(54) FLUX GATE-TYPE RESIDUAL CURRENT DETECTION DEVICE AND CONTROL METHOD OF SAME DEVICE

(71) Applicant: LS ELECTRIC CO., LTD., Anyang-Si, Gyeonggi-do (KR)

(72) Inventor: Jaeshik YOON, Anyang-Si, Gyeonggi-do (KR)

(21) Appl. No.: 19/473,308

(22) PCT Filed: Dec. 22, 2023
(86) PCT No.: PCT/KR2023/021450

§ 371 Date: Oct. 7, 2025

(30) Foreign Application Priority Data
Apr. 12, 2023 (KR) 10-2023-0048354

(51) Int. Cl. G01R 15/18; G01R 19/165; G01R 19/25; G01R 31/52

(52) U.S. Cl. CPC G01R 15/183; G01R 19/16576; G01R 19/25; G01R 31/52

(57) ABSTRACT

The present disclosure relates to a flux gate-type residual current detection device comprising: an oscillation unit which generates a pulse current; a a first core has a first coil wound thereon and is thus magnetized according to the pulse current, a second core has a second coil wound thereon, a third coil wound on the first and second cores is applied, one end of the first coil is connected to the oscillation unit, one end of the second coil is grounded, and a compensation current is applied to the third coil; and a control unit which determines a frequency of the pulse current detects a DC component leakage current of a conductor to be measured and applies, as the compensation current, a reverse current corresponding to the detected DC component leakage current to the third coil.

### CROSS-REFERENCE TO RELATED APPLICATIONS

This application is the National Stage filing under 35 U.S.C. 371 of International Application No. PCT/KR2023/021450, filed on Dec. 22, 2023, which claims the benefit of earlier filing date and right of priority to Korean Application No. 10-2023-0048354, filed on Apr. 12, 2023, the contents of which are all hereby incorporated by reference herein in their entirety.

### FIELD

The present disclosure relates to a residual current detection device for detecting a leakage current or residual current (hereinafter referred to as a residual current), and more particularly, to a flux gate-type residual current detection device that detects a residual current component in a non-contact manner and a control method of the same.

### BACKGROUND

Recently, the demand for DC power sources such as electric vehicles and charging systems is expected to increase, and the supply of new and renewable energy sources such as solar power and fuel cells and energy storage devices is expected to increase. Accordingly, in the field of solar power generation facilities, the technical standards and determination criteria for a DC ground fault interrupting device work processing method for solar power generation facilities have been revised (Ministry of Trade, Industry and Energy Notice No. 2020-659 (Dec. 3, 2020)), and according to the revised notice, it is recommended to install a device that automatically interrupts, when a ground fault occurs in a DC circuit of a solar cell power generation facility, the circuit. Accordingly, regardless of a type of a power conversion device (transformer type, transformerless type), it is recommended to install a type B residual current detector (RCD) or type B earth leakage breaker (ELB) that can detect not only an AC component of a residual current but also a DC component of a residual current.

Meanwhile, many flux gate-type detection devices are being used as detection devices for detecting such a residual current. A flux gate-type residual current detection device, also referred to as a zero flux type, is a method of measuring a current flowing through a conductor to be measured based on a secondary current induced by a magnetic flux generated in a magnetic core due to the current flowing through the conductor to be measured, in which the conductor to be measured is disposed so as to pass through the magnetized core (magnetic core), which is gaining attention because it can accurately detect the current flowing through the conductor to be measured in a non-contact manner.

Meanwhile, in the case of the flux gate type, the current of the conductor to be measured is detected based on a magnetic flux induced in the magnetized core, i.e., magnetic core, as described above. However, a magnitude of a magnetic flux density that increases in response to an increase in an external magnetic field in the core has a limit depending on the characteristics of the core, and a state of the core when a maximum magnetic flux density that can be induced in the core occurs is referred to as a state of magnetic saturation. Furthermore, when the core is magnetically saturated and the flux density becomes maximum, the flux density may not change even if the external magnetic field increases, and in this case, the flux density does not change according to the external magnetic field, and thus it may become impossible to detect a current flowing through the external magnetic field, that is, the conductor to be measured.

However, when an AC current flows through the conductor to be measured, due to the nature of alternating polarity of the AC current, a current that increases the magnetic flux density in a positive direction (e.g., positive (+) current) is applied, and then a current that increases the magnetic flux density in a reverse direction (e.g., negative (−) current) is applied. Therefore, subsequent to increasing the magnetic flux density in a positive direction, a magnetic field that increases the magnetic flux density in a reverse direction is formed, so as to offset the magnetic flux. Therefore, even if the core reaches a state of magnetic saturation, the magnetic flux density of the core may naturally decrease below a maximum magnetic flux density as the magnetic flux is offset by a reverse current due to the polarity switching of the current. However, in the case of a DC current without polarity switching, a magnetic field that forms a magnetic flux density in only one direction may be continuously formed, and thus the magnetic flux may increase without being offset as the external magnetic field increases to continuously accumulate the magnetic flux, and in this case, the core may reach a state of magnetic saturation so as to allow the magnetic flux density to reach the maximum magnetic flux density.

In order to prevent the core from reaching a state of magnetic saturation when detecting a DC current as described above, a method of applying a pulse current having a frequency, that is, a current in which a positive or negative DC current having a predetermined magnitude is switched at a predetermined time cycle, to a coil wound on the core has been introduced. When a pulse current is applied in this manner, the polarity of the magnetic field forming the magnetic flux density in the magnetic core may switch according to the frequency of the pulse current, and thus the core may be prevented from entering a state of magnetic saturation similar to an AC current.

Meanwhile, as described above, the flux gate-type residual current detection device detects a residual current by using a change in magnetic flux density induced in the magnetic core, so theoretically, the residual current can be detected only when the saturation state has not been reached. Therefore, in the case of a flux gate-type residual current detection device, a measurable current may be determined according to the magnetic saturation characteristics of the core. That is, the accuracy and precision of a flux gate-type residual current detection device may be determined according to the magnetic saturation characteristics of the core. Therefore, the efficiency of a flux gate-type residual current detection device may be maximized when a pulse current having a frequency that matches the magnetic saturation characteristics of the core is applied.

Meanwhile, the maximum magnetic flux density of a core may vary depending on a shape or material of the core, a number of turns of a coil wound on the core, a material of the coil, a spacing between turns, and the like. The maximum magnetic flux density that varies depending on the shape, material, or structural characteristics of the core is referred to as the magnetic saturation characteristics of the core. In addition, since the maximum magnetic flux density of the core varies depending on a shape, material or structure of the core, a material of a coil wound on the core, a number of turns of a coil wound on the core, a spacing between turns, and the like, it is difficult for physically completely identical cores to exist, and respective cores may have different magnetic saturation characteristics.

In addition, a pulse signal is usually generated by using a resonant circuit, and when generating the pulse signal (pulse current) using the resonant circuit, a pulse current according to a fixed frequency is applied. In this case, as a time for which a current of a specific polarity is applied becomes longer (the frequency becomes shorter), an amount of current applied to the coil increases, which may increase a magnetizing force. That is, a magnitude of a current applied to the coil wound on the core may vary depending on the frequency of the pulse current, and accordingly, when a pulse signal having a frequency capable of forming a current suitable for the magnetic saturation characteristics of the core is applied, the efficiency of the flux gate-type residual current detection device can be maximized.

However, as described above, since respective cores have different magnetic saturation characteristics, there is a problem in that it is difficult to detect a pulse signal having a frequency that matches the magnetic saturation characteristics of the core to be installed. In addition, even if a frequency of a pulse signal that matches the magnetic saturation characteristics of the core can be known, in a conventional method of generating a pulse current using a resonant circuit as described above, there is a problem in that the design of the resonant circuit itself must be changed in order to change the frequency of the pulse signal. Therefore, it is difficult to apply a frequency of a pulse signal that matches the magnetic saturation characteristics of the core, and thus there is a problem in that a flux gate-type residual current detection device cannot be used efficiently.

Moreover, when generating a pulse signal using a resonant circuit, there is a problem in that the pulse signal may be distorted or its frequency may change due to external shocks such as radiated susceptibility (RS) or conducted susceptibility (CS) or disturbances such as radio noise from a radio, and such a distortion or change in frequency is likely to cause measurement errors.

### SUMMARY

The present disclosure aims to solve the foregoing problems and other problems, and an aspect of the present disclosure is to provide a flux gate-type residual current detection device that further improves accuracy and precision and maximizes efficiency by applying a frequency that matches the magnetic saturation characteristics of a core to a coil wound on the core, and a control method of the device.

In addition, an aspect of the present disclosure is to provide a flux gate-type residual current detection device that can easily apply, when a core is replaced in the flux gate-type residual current detection device, a pulse current having a frequency that matches the magnetic saturation characteristics of a replaced core to the replaced core, and a control method of the device.

In addition, the present disclosure aims to provide a flux gate-type residual current detection device that can precisely and stably measure a residual current regardless of external shock, radio noise or disturbance by generating a pulse current considering core characteristics and applying it to a coil wound on a core, and a control method of the device.

In order to achieve the foregoing or other objectives, according to an aspect of the present disclosure, a residual current detection device according to one embodiment of the present disclosure may include an oscillation unit that generates a pulse current having a preset frequency, a core unit including at least one first core having at least one first coil wound thereon to be magnetized according to the pulse current, a second core having a second coil wound thereon, and a third coil wound on the first core and the second core and to which a compensation current is applied, one end of the first coil being connected to the oscillation unit, one end of the second coil being grounded, and a control unit that determines a frequency of the pulse current according to at least one of the characteristics of the at least one first core, filters out a component having a frequency from a voltage signal of a current induced in the at least one first core to detect a DC component leakage current of a conductor to be measured, and applies a reverse current corresponding to the detected DC component leakage current to the third coil as the compensation current.

In one embodiment, the characteristics of the at least one first core may be at least one of a shape or thickness of the core, a diameter or material of the core, a diameter of a hollow inside the core, a material or number of turns of a coil wound on the core, a spacing between turns of the coil, a manufacturer and manufacturing number of the core, and a type of the conductor to be measured.

In one embodiment, the device may further include a memory in which a plurality of detection frequencies are stored according to respective different characteristics of the at least one first core, wherein the control unit determines one of the plurality of detection frequencies as a frequency of the pulse current based on the characteristics of the at least one first core.

In one embodiment, the control unit may change, when the DC component leakage current of the conductor to be measured is detected according to one of the plurality of detection frequencies, the frequency of the pulse current to another one of the plurality of detection frequencies, detect again the DC component leakage current of the conductor to be measured according to the changed frequency of the pulse current, and determine whether the at least one first core is magnetically saturated to detect a frequency of a pulse current according to a magnetic saturation characteristic of the at least one first core.

In one embodiment, the control unit may determine whether the magnetic saturation of the at least one first core is achieved based on whether a voltage signal detected from the at least one first core generates a square wave.

In one embodiment, the control unit may determine, when a polarity of the voltage signal detected from the at least one first core is switched, whether the voltage signal detected from the at least one first core generates a square wave based on whether there is a voltage change above a predetermined level for a predetermined period of time.

In one embodiment, the control unit may determine, when a magnetic saturation frequency of a pulse current that magnetically saturates the at least one first core is detected, a frequency close to the magnetic saturation frequency from among frequencies of pulse currents that do not magnetically saturate the at least one first core as a pulse current frequency according to the magnetic saturation characteristics of the at least one first core.

In one embodiment, the conductor to be measured may be a test conductor through which a preset magnitude of a DC component of a residual current and an AC component of a residual current flow.

In one embodiment, the oscillation unit may receive a pulse digital signal in which a state of outputting a specific voltage and a state of not outputting voltage are repeated at a preset time cycle, and generate the pulse current in which a positive current and a negative current alternate at the preset time cycle in synchronization with the pulse digital signal, wherein the control unit applies a pulse digital signal that is repeated at the preset time cycle to the oscillation unit based on the frequency of the pulse current determined according to the characteristics of the at least one first core.

In one embodiment, the oscillation unit may have a comparator having a preset reference voltage, wherein the comparator outputs, when a pulse digital signal having a voltage higher than the reference voltage is input, a current having a preset magnitude of a positive voltage, and outputs, when a pulse digital signal having a voltage lower than the reference voltage is input, a current having a preset magnitude of a negative voltage.

In one embodiment, the reference voltage may have a magnitude of half of the specific voltage, wherein the preset magnitude of positive and negative voltages are positive and negative voltages corresponding to the reference voltage.

In order to achieve the foregoing or other objectives, a residual current detection device according to another embodiment of the present disclosure may include an oscillation unit that generates a pulse current having a preset frequency, a core unit including at least one first core having at least one first coil wound thereon to be magnetized according to the pulse current, a second core having a second coil wound thereon, and a third coil wound on the first core and the second core and to which a compensation current is applied, one end of the first coil being connected to the oscillation unit, one end of the second coil being grounded, a residual current detection unit connected to the other end of the at least one first core and the other end of the second core to sum a voltage signal detected from the first core and a voltage signal detected from the second core, an amplification unit that inverts and amplifies a voltage signal according to a voltage signal summation result of the residual current detection unit to generate a compensation current applied to the third coil, and a control unit that determines a frequency of the pulse current according to at least one of the characteristics of the at least one first core, and detects a DC component leakage current flowing through the conductor to be measured based on the compensation current.

In one embodiment, the residual current detection unit may include a differential amplifier having a non-inverting input terminal connected to the other end of the second coil and an inverting input terminal connected to the other end of the first coil to sum a voltage signal corresponding to a DC component residual current of the conductor to be measured and a voltage signal corresponding to an AC component residual current thereof, wherein the differential amplifier is connected to the non-inverting input terminal via a resistor and capacitor whose output terminal acts as a noise filter so as to allow an output of the differential amplifier to be fed back to the non-inverting input terminal.

In one embodiment, the amplification unit may include an operational amplifier having a first input terminal connected to a ground and a second input terminal connected to the output terminal of the differential amplifier via a preset magnitude of a first resistor, wherein the output terminal of the operational amplifier is connected to the second input terminal via a preset magnitude of a second resistor, and connected to the non-inverting input terminal of the differential amplifier so as to allow an output of the operational amplifier to be fed back to the differential amplifier.

In one embodiment, the at least one first core may include a first-first core having a first-first coil wound thereon to which the pulse current is applied, an inverting amplifier that inverts a polarity of the pulse current, a first-second core having a first-second coil wound thereon to which a pulse current having its polarity inverted by the inverting amplifier is applied, and an adding amplifier that synthesizes voltage signals respectively corresponding to secondary currents induced in the first-first coil and the first-second coil.

In one embodiment, the device may further include a memory in which a plurality of detection frequencies are stored according to respective different characteristics of the at least one first core, wherein the control unit determines one of the plurality of detection frequencies as a frequency of the pulse current based on the characteristics of the at least one first core.

In one embodiment, the control unit may change, when the DC component leakage current of the conductor to be measured is detected according to one of the plurality of detection frequencies, the frequency of the pulse current to another one of the plurality of detection frequencies, detect again the DC component leakage current of the conductor to be measured according to the changed frequency of the pulse current, and determine whether the at least one first core is magnetically saturated to detect a frequency of a pulse current according to a magnetic saturation characteristic of the at least one first core.

In one embodiment, the control unit may determine, when a magnetic saturation frequency of a pulse current that magnetically saturates the at least one first core is detected, a frequency close to the magnetic saturation frequency from among frequencies of pulse currents that do not magnetically saturate the at least one first core as a pulse current frequency according to the magnetic saturation characteristics of the at least one first core.

The effects of a flux gate-type residual current detection device and a control method of the device according to the present disclosure will be described as follows.

According to at least one of embodiments of the present disclosure, the present disclosure may generate a pulse current applied to a coil wound on a core of a residual current detection device through a control unit that intermittently outputs a predetermined magnitude of a current according to a preset time interval, change a frequency of the pulse current by adjusting the preset time interval, and detect a frequency of the pulse current that matches the magnetic saturation characteristics of the core based on the changed frequency of the pulse current. Furthermore, a pulse current of the detected frequency may be applied to a coil wound on the core, thereby having an effect of maximizing a measurement efficiency of the flux gate-type residual current detection device, and maximizing precision and accuracy.

In addition, the present disclosure may detect, when a core of a flux gate-type residual current detection device is replaced, a frequency of a pulse signal that matches the characteristics of the replaced core. Therefore, the frequency of the pulse current may be easily changed to a frequency that matches the magnetic saturation characteristics of the replaced core. Therefore, there is an effect that can stably maintain the measurement efficiency, precision and accuracy of the residual current detection device at a maximum level regardless of the change of the core.

In addition, the present disclosure may apply a pulse current to a coil wound on a flux gate-type core based on a digital pulse signal according to a voltage with a predetermined magnitude that is intermittently output according to a preset time interval generated by a control unit. Therefore, a resonant circuit may not be used to generate a pulse current, thereby having a residual current detection effect that is robust to external shock, radio noise, or disturbance.

### BRIEF DESCRIPTION OF THE DRAWINGS

FIG. 1 is a circuit diagram showing a circuit configuration of a residual current detection device that compensates for a DC component compensation current according to a first embodiment of the present disclosure.

FIG. 2 is a circuit diagram showing a circuit configuration of a residual current detection device that applies a compensation current according to a detected leakage current according to a second embodiment of the present disclosure.

FIGS. 3 to 5 are exemplary diagrams showing configurations of a core unit provided in a residual current detection device according to embodiments of the present disclosure.

FIG. 6 is a flowchart showing an operation process of detecting a frequency of a pulse current that matches the magnetic saturation characteristics of a core in a residual current detection device according to embodiments of the present disclosure.

FIG. 7 is a graph showing a hysteresis loop showing the magnetic saturation characteristics of a core and a graph showing the magnetic flux density characteristics of a core according to a current in the core.

FIG. 8 is a flowchart showing an operation process of applying a DC component compensation current detected when detecting a residual current of a conductor to be measured to each core in a residual current detection device according to a first embodiment of the present disclosure.

FIG. 9 is a flowchart showing an operation process of initializing a core according to a state of magnetic saturation of a core in a residual current detection device according to a first embodiment of the present disclosure.

FIG. 10 is an exemplary diagram showing an output waveform of a DC component detection core according to a state of the core in a residual current detection device according to embodiments of the present disclosure.

### DETAILED DESCRIPTION

It should be noted that the technical terms used herein are merely used to describe a specific embodiment, but are not intended to limit the present disclosure. In addition, a singular expression used herein may include a plural expression unless clearly defined otherwise in the context. A suffix “module” or “part” used for elements disclosed in the following description is merely intended for easy description of the specification, and the suffix itself is not intended to have any special meaning or function.

As used herein, terms such as “comprise” or “include” should not be construed to necessarily include all elements or steps described herein, and should be construed not to include some elements or some steps thereof, or should be construed to further include additional elements or steps.

In addition, in describing technologies disclosed herein, when it is determined that a detailed description of known technologies related thereto may unnecessarily obscure the subject matter disclosed herein, the detailed description will be omitted.

In addition, the accompanying drawings are provided only for a better understanding of the embodiments disclosed in this specification and are not intended to limit technical concepts disclosed in this specification, and therefore, it should be understood that the accompanying drawings include all modifications, equivalents and substitutes within the concept and technical scope of the present disclosure. In addition, not only respective embodiments described below, but also combinations of embodiments may, of course, be included within the concept and technical scope of the present disclosure as modifications, equivalents or substitutes.

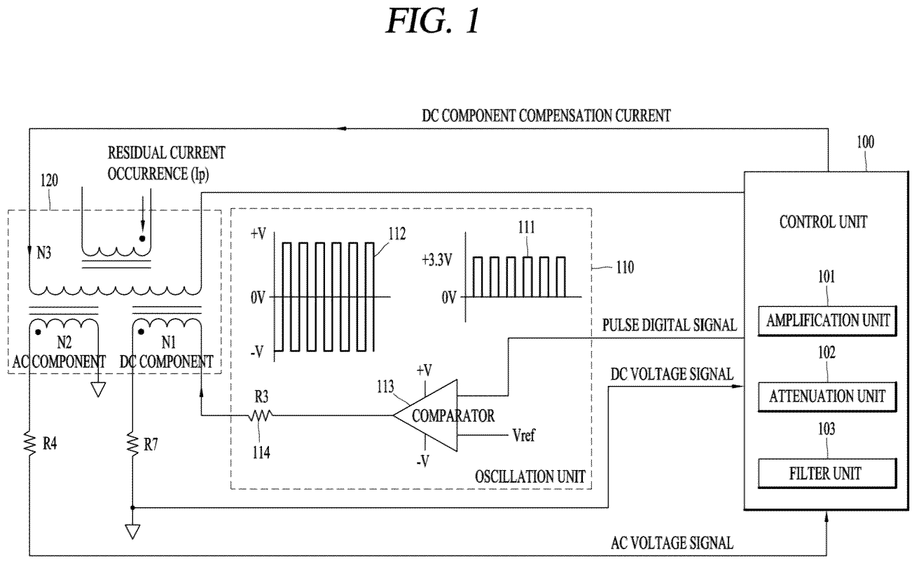

FIG. 1 is a circuit diagram showing a circuit configuration of a flux gate-type residual current detection device that compensates for a DC component compensation current according to a first embodiment of the present disclosure.

Referring to FIG. 1, a residual current detection device according to an embodiment of the present disclosure may be configured to include a control unit (micro controller unit, MCU) 100, an oscillation unit 110 connected to the control unit 100 and controlled by the control unit 100, an output unit (not shown), and a core unit 120 including at least one core whose magnetic flux changes according to a DC component leakage current or an AC component leakage current flowing through a conductor. The elements shown in FIG. 1 are not essential for implementing a flux gate-type residual current detection device, and thus, the residual current detection device described herein may have more or fewer elements than those listed above.

First, the control unit 100 may intermittently output a current having a specific voltage at preset time intervals. That is, the control unit 100 may output a current having the specific voltage (e.g., 3.3 V) for a predetermined period of time at the preset time cycle, and may not output a current for a next predetermined period of time. Accordingly, a pulse digital signal 111 that repeats a state of outputting the specific voltage (e.g., 3.3 V) and a state of outputting 0 V (a state in which no current is output) at the preset time cycle may be output from the control unit 100.

Meanwhile, the control unit 100 may determine a frequency of the pulse digital signal 111 by changing the preset time interval. For example, the control unit 100 may output a current at the specific voltage for 1/3600 seconds. Furthermore, subsequent to stopping the output of the current for 1/3600 second, a current at the specific voltage may be output again for 1/3600 second. In this case, a state in which the current at the specific voltage is output and an state in which 0 V is output may alternate at a cycle of 1/1800 seconds. That is, the pulse digital signal 111 having a frequency of 1.8 KHz may be generated.

The pulse digital signal 111 generated from the control unit 100 may be applied to the oscillation unit 110 that generates a pulse current from the applied pulse digital signal 111.

In this case, the oscillation unit 110 may generate a pulse current synchronized to the pulse digital signal 111 applied from the control unit 100. To this end, the oscillation unit 110 may include a comparator 113 in which a preset voltage is set as a reference voltage. In this case, the comparator 113 may output a current having a positive (+) voltage when a pulse digital signal having a voltage higher than the reference voltage is input, and may output a current having a negative (−) voltage when a pulse digital signal having a voltage lower than the reference voltage is input. Accordingly, a pulse current in which positive and negative currents alternate may be generated depending on a frequency of the pulse digital signal 111. In this case, the reference voltage may be a half of the specific voltage.

As an example, when the specific voltage is 3.3 V as in the foregoing example, the reference voltage may be set to 1.65 V. Then, when the pulse digital signal 111 output from the control unit 100 is 3.3 V, a positive voltage (+1.65 V) of 1.65 V may be generated, and when the pulse digital signal output is 0 V, a negative voltage (−1.65 V) of 1.65 V may be generated. That is, a pulse voltage 112 with alternating positive and negative voltages of 1.65 V per cycle may be generated.

Furthermore, the oscillation unit 110 may apply a pulse current according to the generated pulse voltage 112 to a coil wound on at least one core for detecting a DC component residual current among the cores constituting the core unit 120. In this case, among the cores of the core unit 120, a core for detecting an AC component residual current may induce a current corresponding to a magnetic flux due to an AC component of a current Ip flowing through a conductor to be measured.

Meanwhile, the oscillation unit 110 may further include a resistor 114 for determining a magnitude of a current to be applied to the core unit 120. Here, the polarity and magnitude of the pulse current may be determined (I=V/R) according to the polarity of the pulse voltage 112 and the magnitude of the resistor 114 to the pulse voltage 112. Furthermore, when a pulse current is applied, the core may be magnetized based on a magnetizing force according to a magnitude of the applied current, and a magnetic flux may be formed around the magnetized core.

Meanwhile, the core unit 120 may include at least one DC component detection core for detecting a DC component residual current and at least one AC component detection core for detecting an AC component residual current. In this case, each core may have a ring structure or annular structure with a hole formed in the center through which the conductor to be measured may pass. Additionally, the at least one DC component detection core may be wound with a first coil N1 for magnetizing the core, and the AC component detection core may be wound with a second coil N2 for magnetizing the core. Furthermore, a third coil N3 for applying a compensation current may be wound on both the at least one DC component detection core and the AC component detection core.

When a conductor to be measured is inserted through the central hole of the cores formed in this manner to detect a residual current, a magnetic flux may be generated in each core due to the current Ip flowing through the conductor to be measured. Then, a current (secondary current) may be induced in the coil wound on each core to offset the generated magnetic flux. Furthermore, the control unit 100 may detect a voltage signal corresponding to an AC component residual current and a voltage signal corresponding to a DC component residual current flowing through the conductor to be measured according to a magnitude of a secondary current induced in each core.

Meanwhile, voltage signals detected from the core unit 120 may have a fine magnitude that is difficult to detect in the control unit 100. Therefore, the control unit 100 may include an amplification unit 101 that can amplify voltage signals detected from the core unit 120 to a range that can be recognized by the control unit 100. In addition, the control unit 100 may include a low pass filter (LPF) (not shown) for removing a pulse signal applied from the oscillation unit 110 and noise from the core, and may include an analog digital converter (ADC) (not shown) for converting the amplified voltage signal within a range that can be recognized by the control unit 100 into a digital signal.

Meanwhile, when the residual current is an AC current, a magnetic flux may be automatically offset by the polarity switching of the current. However, if the residual current is a DC current, the polarity switching of the current is not carried out, and thus the magnetic flux cannot be offset. Therefore, the magnetic flux may be accumulated.

When the non-offset magnetic flux is accumulated, the accumulated magnetic flux component may be summed as a DC component of the residual current. Furthermore, the accumulated magnetic flux component may be measured as a residual current. Therefore, the control unit 100 may apply a compensation current to a coil wound on a DC component detection core to offset the accumulated magnetic flux component. In this case, in order to offset the magnetic flux, a current capable of generating a magnetic flux in an opposite direction must be applied, and therefore, a current having the same magnitude as the measured DC component residual current but an opposite polarity, that is, a reverse current, may be applied to the core unit 120 as the compensation current.

Meanwhile, when a DC component of a residual current flows through the conductor to be measured, an AC component of a residual current may increase due to the DC component of the residual current. Therefore, the third coil N3 may be wound on both the AC component detection core as well as the at least one DC component detection core. Accordingly, a magnetic flux according to an error component (DC component leakage current component) included in an AC component leakage current may be offset by the compensation current.

In order to apply the compensation current, the control unit 100 may detect a voltage signal corresponding to a secondary current induced in the at least one DC component detection core through a resistor R7.

Here, the DC component detection core may be a core magnetized by a first coil N1 wound on the DC component detection core. Furthermore, a pulse current generated from the oscillation unit 110 may be applied to the first coil N1. Therefore, the secondary current induced in the at least one DC component detection core may include an AC component according to the pulse current applied to the first coil N1.

In this case, the control unit 100 may include a filter unit 103 for filtering the AC component from the secondary current induced in the DC component detection core. For example, the filter unit 103 may filter a component having a frequency from the voltage signal of the secondary current induced in the DC component detection core. Then, a voltage signal corresponding to a pure DC component residual current from which a component according to a pulse current is removed may be detected from the secondary current induced in the DC component detection core.

Then, the control unit 100 may apply a reverse current corresponding to the DC component residual current detected through the filter unit 103 as a compensation current to the core unit 120, more specifically, to the third coil N3 for applying the compensation current. Accordingly, a magnetic flux due to the DC component residual current flowing through the conductor to be measured may be offset not only in the DC component detection core but also in the AC component detection core.

Here, the compensation current may be a microcurrent that is difficult for the control unit 100 to directly control. Accordingly, the control unit 100 may further include an attenuation unit 102 for attenuating a current output from the control unit 100. Furthermore, the control unit 100 may control an attenuation amount of the attenuation unit 102 to apply a compensation current attenuated to a microscopic level below a level that can be controlled by the control unit 100 to the third coil N3.

Meanwhile, when the magnetic flux due to the DC component residual current flowing through the conductor to be measured is offset by the compensation current, the control unit 100 may detect a voltage signal corresponding to the secondary current induced in the AC component detection core through a resistor R4. Furthermore, a voltage signal corresponding to the secondary current induced in the AC component detection core may be detected as an AC component residual current. Furthermore, the control unit 100 may sum a voltage signal (DC component residual current) detected by filtering the secondary current induced in the DC component detection core and a voltage signal (AC component residual current) detected from the secondary current induced in the AC component detection core to calculate an amount of a total residual current Ip flowing through the conductor to be measured. Furthermore, an output unit may be controlled according to the calculated amount of the residual current to output the detected amount of the residual current. Additionally, a signal related to the detection of the residual current may be output.

Here, a signal related to the detection of the residual current may be a trip signal for controlling a circuit breaker. In this case, the circuit breaker that receives a trip signal from the output unit may separate an internal circuit connected to a residual current detection device from a line to prevent a residual current from flowing into the internal circuit or into the line.

Alternatively, a signal related to the detection of the residual current may be a notification signal that notifies a preset system of the occurrence of the residual current. In this case, the system may be a control system that controls an internal circuit connected to the residual current detection device. Then, the control system may control a circuit breaker to isolate the internal circuit from the line based on the notification signal. Alternatively, the control system may transmit information to at least one other device or apparatus to notify the occurrence of the residual current, or carry out a process to deal with the occurrence of the residual current.

Meanwhile, a density of a magnetic flux formed in the core may be determined according to a magnetizing force that magnetizes the core. Furthermore, the magnetizing force may vary in magnitude depending on a magnetizing current that magnetizes the core, that is, a current flowing through the coil wound on the core. In this case, when the current flowing through the coil is an AC current with alternating negative and positive currents, the flow of the current may be limited depending on the frequency by an inductive reactance of the coil. That is, even if the AC current has the same magnitude, as the frequency increases, the current flow in the coil may be limited, and accordingly, the magnitude of the magnetizing current may also vary.

However, as described above, since the pulse current also has the characteristics of an AC current with alternating negative and position currents at a predetermined time cycle, the flow of the current may be limited depending on the frequency of the pulse current due to an inductive reactance of the coil. That is, the higher the frequency, the smaller the magnetizing current, and the lower the frequency, the larger the magnetizing current. Furthermore, as the magnitude of the magnetizing current increases, the magnitude of the magnetic flux density may increase proportionally.

Therefore, in the case of the present disclosure in which a pulse current according to a specific frequency is generated according to a pulse digital signal generated from the control unit 100, a magnetizing current flowing through the coil may be changed by only changing the frequency of the pulse digital signal applied to the oscillation unit 110 by the control unit 100 without having to change a resistance of the oscillation unit 110 and a voltage of the pulse digital signal so as to change a magnetic flux density formed around the DC component detection core. That is, in the case of the present disclosure, the control unit 100 may change a time interval at which a current having the specific voltage is output according to different frequencies of a pulse current, thereby changing a magnetic flux density formed around the core without having to change a circuit configuration of the oscillation unit 110.

Meanwhile, as described above, when a magnetizing current forming the magnetic saturation characteristics of the core, that is, a maximum magnetic flux density, is generated, the accuracy and precision of the flux gate-type residual current detection device may be maximized, and the efficiency of the flux gate-type residual current detection device may be maximized. Accordingly, in the present disclosure, the control unit 100 may detect a frequency of a pulse digital signal at which a magnetizing current forming a maximum magnetic flux density of a DC component detection core is generated while changing the frequency of the pulse digital signal.

As an example, the control unit 100 may detect, when a test conductor through which a preset DC component residual current flows is passed through each core, a DC component residual current detected from the test conductor while changing the frequency of the pulse current. In this case, when the frequency of the pulse current decreases, a magnetizing current of a DC component detection core may increase due to an inductive reactance of the first coil N1, and the magnetic flux density may increase, when the magnetizing current increases, so as to allow more secondary current to be induced in the DC component detection core. Therefore, more DC component residual current may be detected. In this case, when the magnetizing current increases and the magnetic flux reaches a maximum magnetic flux density, a secondary current having the same magnitude may be induced in a DC component detection core regardless of a change in the frequency of the pulse current, and accordingly, the same DC component residual current may be detected. That is, a pulse current frequency when a DC component residual current is maintained constant even when the frequency of the pulse current increases or decreases may be a frequency of the pulse current that generates a magnetizing current forming a maximum magnetic flux density, that is, a frequency of the pulse current corresponding to the magnetic saturation characteristics of the core.

Meanwhile, in order to shorten a period of time for detecting the frequency of the pulse current corresponding to the magnetic saturation characteristics of the core, the control unit 100 may set a specific frequency range according to the structural characteristics of the core, such as a shape or material of the core, or a material, a number of turns, or a spacing between turns of the core.

To this end, the residual current detection device according to an embodiment of the present disclosure may have a memory (not shown) in which different detection frequency ranges are stored according to at least one of a diameter, material, shape of a DC component detection core, or characteristics of a coil wound on the core. Alternatively, the memory may store different detection frequency ranges depending on a type of conductor to be measured or a manufacturer or serial number of a core for which a DC component residual current is to be detected. In this case, the control unit 100 may detect a frequency of a pulse current that matches the magnetic saturation characteristics of a core based on a detection frequency range according to at least one of structural characteristics such as a diameter, material or shape of the core, or a type of a conductor to be measured, and manufacturing information such as a manufacturer or serial number of the core, among different detection frequency ranges stored in the memory.

In this case, the control unit 100 may detect a frequency of a pulse current that matches the magnetic saturation characteristics of a DC component detection core according to a preset frequency change unit corresponding to each detection frequency range. As an example, the control unit 100 may determine a detection frequency range corresponding to 1.3 KHz or more and less than 1.8 KHz based on at least one of the structural characteristics of a core or a type of a conductor to be measured, and manufacturing information of the core. Furthermore, a frequency of a pulse current corresponding to the magnetic saturation characteristics of a core may be detected by changing a frequency by preset units within the determined detection frequency range. In this case, a frequency change unit corresponding to a detection frequency range of 1.3 KHz or more and less than 1.8 KHz may be 0.05 KHz. In this case, when the detection frequency range changes, the frequency change unit may also change.

Meanwhile, the control unit 100 may detect whether the DC component detection core is magnetically saturated based on a waveform of a secondary current detected from the DC component detection core. Furthermore, when the DC component detection core is in a state of magnetic saturation, the DC component compensation current may be amplified to a magnitude according to the magnetic saturation characteristics of the core and applied to the third coil N3.

In this case, since the DC component detection core cannot be magnetized beyond the maximum magnetic flux density state due to the magnetic saturation characteristics of the core, when a compensation current corresponding to a current that forms a magnetizing force that allows the DC component detection core to reach a state of magnetic saturation, that is, a reverse current, is applied, a magnetic flux of the magnetically saturated core may be offset, and thus the DC component detection core may be demagnetized.

Then, the control unit 100 may apply a pulse current having a frequency according to the magnetic saturation characteristics of the core again to a coil wound on the DC component detection core so as to magnetize the DC component detection core according to the magnetic saturation characteristics of the core.

Meanwhile, FIG. 1 has described a structure in which the control unit 100 detects a DC component leakage current and applies a compensation current based on the detected DC component leakage current. However, in the case of a pulse current, since it has the characteristics of an AC current in which the polarity is inverted at regular intervals, it may of course be possible to apply a compensation current based on a residual current obtained by summing an AC component residual current and a DC component residual current having an AC characteristic according to the applied pulse current, and to detect the summed residual current based on the applied compensation current.

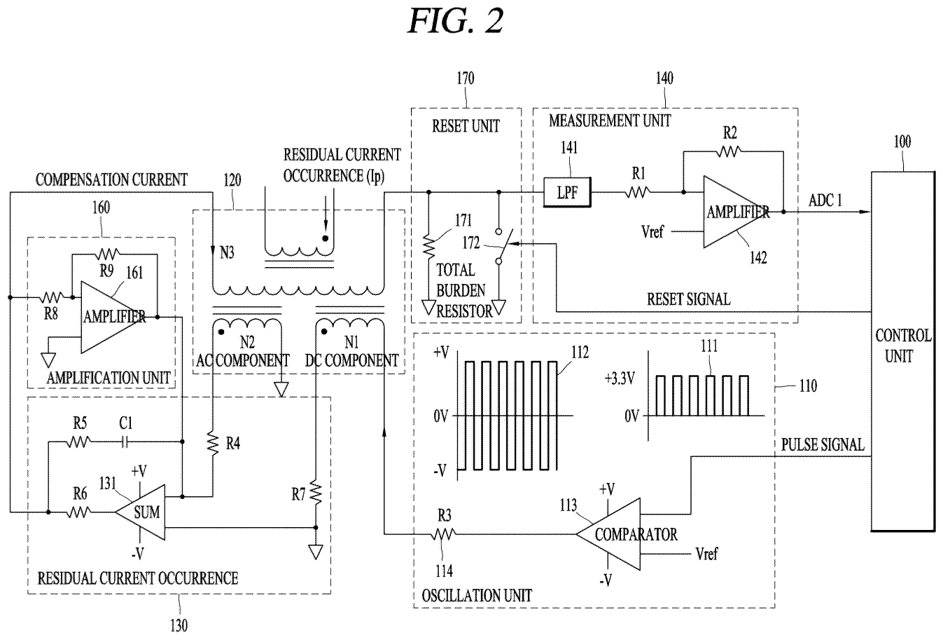

FIG. 2 is a circuit diagram showing a circuit configuration of a flux gate-type residual current detection device that applies a compensation current according to a detected leakage current according to the second embodiment of the present disclosure.

Referring to FIG. 2, a residual current detection device according to a second embodiment of the present disclosure may be configured to include a residual current detection unit 130 and an amplification unit 160. Furthermore, the residual current detection device may be configured to include a reset unit 170 including a total burden resistor and a measurement unit 140 that amplifies a compensation current and inputs it to the control unit 100.

In more detail, the residual current detection unit 130 may include a differential amplifier 131. Furthermore, an output terminal of the differential amplifier 131 via a resistor R6 may be fed back to a non-inverting input terminal V+ of the differential amplifier 131 via a resistor R5 and a capacitor C1 that act as a noise filter. Furthermore, the other end of the first coil N1 to allow one end thereof to be connected to the oscillation unit 110 to receive a pulse current may be connected to an inverting input terminal V− of the differential amplifier 131 via a resistor R7, and one end of the second coil N2 to allow the other end thereof to be grounded may be connected to a non-inverting input terminal V+ of the differential amplifier 131 via a resistor R4.

Accordingly, the differential amplifier 131 may differentially amplify a voltage signal corresponding to a DC component residual current of a conductor to be measured input through an inverting input terminal V− and a voltage signal corresponding to an AC component residual current of a conductor to be measured input through a non-inverting input terminal V+. That is, the differential amplifier 131 may amplify by summing a voltage signal corresponding to a DC component residual current and a voltage signal corresponding to an AC component residual current that are detected in the conductor to be measured.

Here, the DC component detection core may be a core magnetized by the first coil N1 to which a pulse current is applied. Therefore, the voltage signal corresponding to the DC component residual current may be a voltage signal whose polarity is inverted depending on the frequency of the pulse current applied to the first coil N1. That is, the voltage signal detected by the DC component detection core has the characteristics of an AC current according to the applied pulse current, even though it corresponds to the DC component residual current of the conductor to be measured. Therefore, unlike a DC current where only a specific polarity of current is applied, since the polarity is inverted, a magnetic flux of the core may be offset depending on the frequency of the pulse current. Therefore, as illustrated in a first embodiment of the present disclosure shown above in FIG. 1, instead of separately compensating for a DC component residual current, as shown in FIG. 2, a voltage signal detected by the AC component detection core and a voltage signal detected by the DC component detection core may be summed (residual current detection unit 130), and a compensation current corresponding to the summed total voltage signal may be generated.

Meanwhile, the amplification unit 160 may be configured to include an operational amplifier 161 to invert and amplify the voltage signal attenuated by the resistors R4, R7, R6 and the filter R5, C1 using the resistors R8, R9. The operational amplifier 161 may invert and amplify a voltage signal output from an output terminal of the differential amplifier 131 of the residual current detection unit 130, that is, a DC voltage signal (corresponding to a DC component residual current) and an AC voltage signal (corresponding to an AC component residual current) summed by the residual current detection unit 130.

Here, a non-inverting input terminal V+ of the operational amplifier 161 may be grounded, and an output terminal of the differential amplifier 131 of the residual current detection unit 130 via the resistor R8 and the resistor R6 may be connected to an inverting input terminal V− thereof. Furthermore, an output terminal of the operational amplifier 161 may be fed back to a non-inverting input terminal V+ of the differential amplifier 131 of the residual current detection unit 130. Therefore, through the inversion amplification of the amplification unit 160, an inverse voltage of the DC voltage signal and the AC voltage signal summed by the residual current detection unit 130, that is, a compensation current, may be output from the output terminal of the differential amplifier 131 of the residual current detection unit 130.

Meanwhile, the output terminal of the differential amplifier 131 of the residual current detection unit 130 may be connected to one end of the third coil N3 wound on both the AC component detection core and the at least one DC component detection core. Accordingly, the compensation current may be applied to the third coil N3. Accordingly, an error due to a residual current may be compensated.

Then, the compensation current may be output in the form of a voltage signal generated according to a total burden resistor 171 of the reset unit 170 connected to the other end of the third coil N3. In this case, the voltage signal may include a pulse signal applied from the oscillation unit 110 and noise from the core. Accordingly, the measurement unit 140 may include a low pass filter (LPF) 141 connected to the other end of the third coil N3, and may include an amplifier 142 that amplifies a voltage signal within a range that can be recognized by the control unit 100 using a preset reference voltage Vref. Furthermore, a voltage signal amplified to a range that can be recognized by the control unit 100 through the amplifier 142 may be input to an analog digital converter (ADC) channel of the control unit 100.

Then, a magnitude of the compensation current may be detected through the ADC (not shown) provided in the control unit 100. Here, the compensation current, which is a reverse current of a current obtained by summing an AC component residual current and a DC component residual current of a conductor to be measured, may be equal to a magnitude of a residual current of the conductor to be measured. Therefore, a magnitude of the compensation current may be detected to detect a residual current of the conductor to be measured.

Meanwhile, the reset unit 170 may be disposed between the other end of the third coil N3 and the measurement unit 140, and may be configured to include a reset switch 172 that initializes and demagnetizes the cores of the core unit 120 according to a reset signal applied from the total burden resistor 171 and the control unit 100.

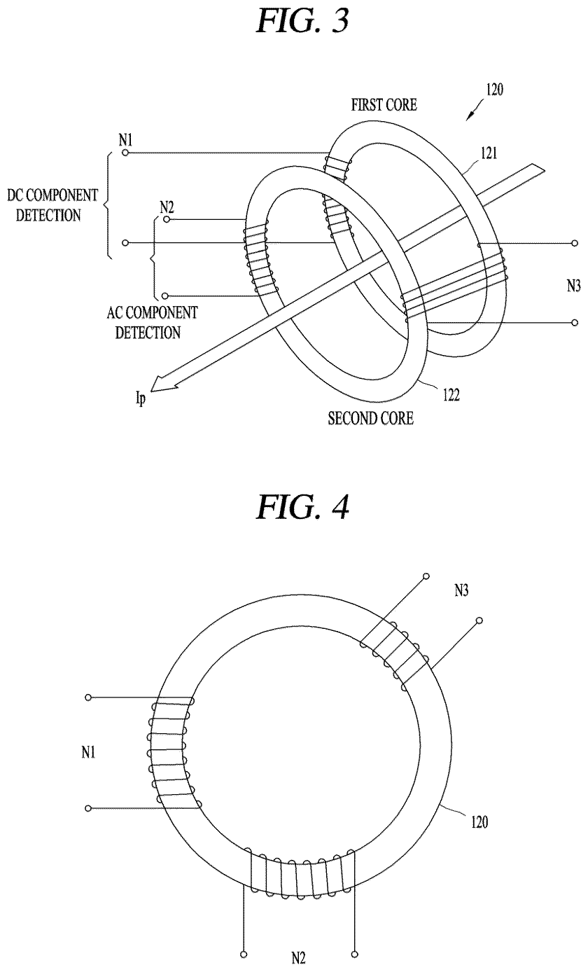

Meanwhile, FIGS. 3 to 5 are exemplary diagrams showing different configurations of the core unit 120 provided in the foregoing residual current detection device according to first and second embodiments of the present disclosure.

First, referring to FIG. 3, an example is shown in which the core unit 120 of the residual current detection device according to embodiments of the present disclosure is configured with a first core 121 for detecting a DC component residual current and a second core 122 for detecting an AC component residual current (dual core structure). In this case, a first coil N1 for magnetizing the first core 121 may be wound on the first core 121, and a second coil N2 for magnetizing the second core 122 may be wound on the second core 122. Furthermore, a third coil N3 for applying a compensation current may be wound on both the first core 121 and the second core 122.

When the core unit 120 is configured to include two cores as described above, the DC component residual current and the AC component residual current may be detected respectively according to secondary currents induced in different separate cores. In this case, the residual current detection device according to an embodiment of the present disclosure may remove an AC component having a frequency from a secondary current detected through the first core 121 to detect a DC component residual current, and compensate for an error according to the detected DC component residual current, and then detect an AC component residual current from a secondary current detected through the second core 122. Furthermore, the detected DC component residual current and AC component residual current may be summed to detect a total residual current flowing through a conductor to be measured may be detected (first embodiment of the present disclosure). Alternatively, the residual current detection device according to an embodiment of the present disclosure may sum a voltage signal of a secondary current detected through the first core 121 and a voltage signal of a secondary current detected through the second core 122, and apply a compensation current corresponding to the summed voltage signal to the third coil N3 wound on both the first core 121 and the second core 122. Furthermore, a total residual current flowing through the conductor to be measured may also be detected based on the compensation current (second embodiment of the present disclosure).

Meanwhile, as shown in FIG. 3, in addition to a structure including two cores, a DC current component of a residual current and an AC current component of a residual current may be detected through one core. FIG. 4 shows an example in which a core unit is configured with one core as described above.

Referring to FIG. 4, an example (single core structure) is shown in which the core unit 120 is configured with one core for detecting a DC current component and an AC current component. In this case, a second coil N2, one end of which is grounded, may be wound on a core. Additionally, a first coil N1 having one end connected to the oscillation unit 110 that applies a pulse current may be wound on the core. Furthermore, the third coil N3 for applying a compensation current may be wound on the core.

In this case, a secondary current corresponding to an AC component of a residual current flowing through the conductor to be measured may be induced in the first coil N1. Furthermore, a secondary current corresponding to a DC component of a residual current flowing through the conductor to be measured may be induced in the second coil N2. Additionally, a compensation current according to a secondary current corresponding to the AC component of the residual current and a secondary current corresponding to the DC component of the residual current may be applied to the third coil N3. Furthermore, based on the compensation current, a total amount of residual current flowing through the conductor to be measured may be detected.

Meanwhile, in the foregoing description according to a first embodiment of the present disclosure, a configuration in which the control unit 100 filters an AC component having a frequency from a voltage signal of a secondary current induced from the first core 121 in order to detect a DC component residual current has been described. However, in contrast, when two identical cores magnetized with opposite polarities are used, it may of course be possible to detect a DC component of a residual current without filtering the AC component.

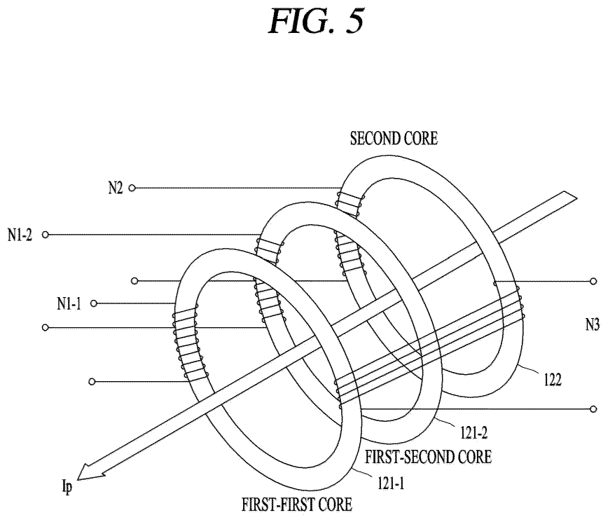

FIG. 5 shows an example in which the core unit 120 is configured as a triple core structure having two cores for detecting a DC component residual current and one core for detecting an AC component residual current.

When the core unit 120 has a triple core structure as shown in FIG. 5, a first-first core 121-1 and a first-second core 121-2 may be cores that detect a DC component residual current. Additionally, the second core 122 may be a core that detects an AC component residual current.

In this case, a second coil N2 with one end grounded may be wound on the second core 122. Additionally, a first-first coil N1-1 may be wound on the first-first core 121-1, and a first-second coil N1-2 may be wound on the first-second core 121-2. Furthermore, pulse currents having the same magnitude and frequency but different polarities may be applied to the first-first coil N1-1 and the first-second coil N1-2. That is, while a pulse current output from the oscillation unit 110 is applied to one end of the first-first coil N1-1 and the first-second coil N1-2, a pulse current with an inverted sign may be applied to the other end through an inverting amplifier or the like.

Furthermore, when the conductor to be measured is inserted through a hole inside each core of the core unit 120, a secondary current corresponding to a DC component of a residual current flowing through the conductor to be measured may be induced in each of the first-first coil N1-1 and the first-second coil N1-2. In this case, since pulse currents having opposite polarities are applied to the first-first coil N1-1 and the first-second coil N1-2, secondary currents applied to the first-first coil N1-1 and the first-second coil N1-2 may have opposite polarities.

Meanwhile, the respective other ends of the first-first coil N1-1 and the first-second coil N1-2 may be connected in parallel to an inverting input unit V− of an adding amplifier whose non-inverting input unit V+ is grounded. Accordingly, voltage signals corresponding to secondary currents induced in the first-first coil N1-1 and the first-second coil N1-2 may be synthesized in the adding amplifier. Then, a frequency component according to the pulse current may be offset through the synthesis, and accordingly, a DC component residual current in a form of a pure DC may be detected.

Meanwhile, in the case of the residual current detection device according to a second embodiment of the present disclosure, a DC component residual current calculated according to a result of the synthesis of the adding amplifier may be applied to the third coil N3 to compensate for an error according to the DC component residual current. Furthermore, based on a secondary current induced from the second core 122, an AC component residual current may be detected, and a total amount of residual current of the conductor to be measured may be calculated based on the detected DC component residual current and AC component residual current. Furthermore, based on the calculated total amount of residual current, the output unit (not shown) may be controlled to output a result of determining a residual current, and output, when the residual current is detected, a signal related to the detection of the residual current.

Alternatively, in the case of the residual current detection device according to a second embodiment of the present disclosure, an output terminal of the adding amplifier may be connected to one end (e.g., inverting input terminal V−) of the input unit of the differential amplifier 131 of the residual current detection unit 130. Furthermore, the other end of the second coil N2 may be connected to the other end (e.g., non-inverting input terminal V+) of the input unit of the differential amplifier 131. Accordingly, the differential amplifier 131 may amplify by summing a voltage signal of a DC component residual current detected from the first-first core 121-1 and the first-second core 121-2 and a voltage signal of an AC component residual current detected from the second core 122. Furthermore, the summed voltage signal may be applied to the amplification unit 160 to be inverted and amplified. Furthermore, a compensation current corresponding to the summed voltage signal may be applied to the third coil N3. Furthermore, the control unit 100 may measure the compensation current through the measurement unit 140 to calculate a total amount of residual current of the conductor to be measured.

Meanwhile, in the drawings of FIGS. 3 to 5, the configurations of core units 120 with different structures have been described. However, regardless of the structure of the core unit 120, a pulse current generated from the oscillation unit 110 may be applied to a core that detects a DC component of a residual current, among the cores of the core unit 120. Here, the oscillation unit 110 may determine a frequency of the pulse current according to a frequency of a pulse digital signal output from the control unit 100, and the control unit 100 may detect a frequency of a pulse current that matches the magnetic saturation characteristics of a core that detects the DC component residual current by changing the frequency of the pulse digital signal. Therefore, the present disclosure may apply a pulse current at an optimal frequency that matches the magnetic saturation characteristics of a core regardless of the structure of the core unit 120, thereby maximizing the accuracy, precision, and efficiency of the residual current detection device.

Meanwhile, in the foregoing description, the circuit structures of the flux gate-type residual current detection device according to embodiments of the present disclosure have been described in detail.

In the following description, in a flux gate-type residual current detection device according to first or second embodiment of the present disclosure, an operation process of applying a pulse current at an optimal frequency that matches the magnetic saturation characteristics of a core to detect a residual current of a conductor to be measured will be described in detail.

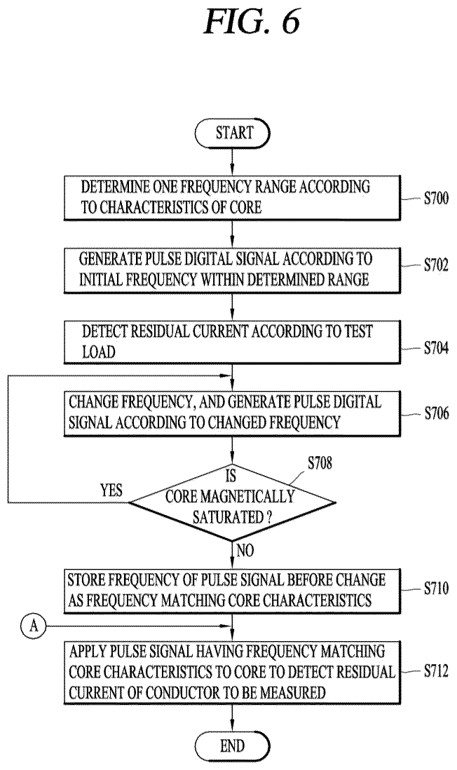

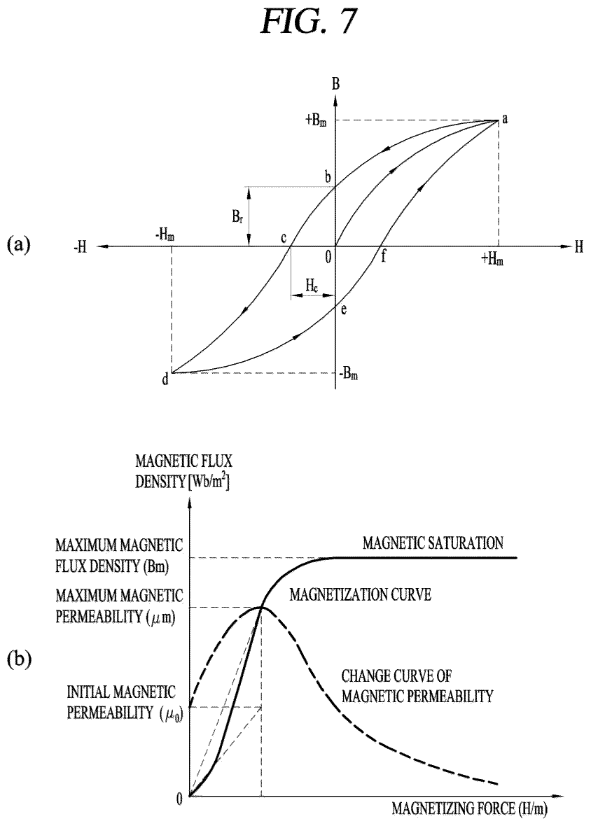

First, FIG. 6 is a flowchart showing an operation process of detecting a frequency of a pulse current that matches the magnetic saturation characteristics of a core in a residual current detection device according to embodiments of the present disclosure. Furthermore, FIG. 7 is a graph showing a hysteresis loop showing the magnetic saturation characteristics of a core and a graph showing the magnetic flux density characteristics of a core according to a current in the core.

First, referring to FIG. 6, the control unit 100 of the residual current detection device according to embodiments of the present disclosure may first determine a detection frequency range for detecting a pulse current frequency that matches the magnetic saturation characteristics of the core (S700).

As an example, the detection frequency range may vary depending on various characteristics of the core to which the pulse current is applied. For example, different detection frequency ranges may be determined depending on the physical characteristics of the core, such as a shape (e.g., ring shape or open ring shape) or thickness of the core, a diameter of the core, a material of the core, a diameter of a hollow inside the core, and the like. Alternatively, different detection frequency ranges may be determined depending on the characteristics of the coil, such as a material of a coil wound on the core, a number of turns of the coil, and a spacing between turns of the coil. Alternatively, different detection frequency ranges may be determined depending on the characteristics of the conductor to be measured, such as a type of the conductor to be measured, a manufacturer of the core, or a manufacturing number (serial number) of the core, or the manufacturing information of the core. The control unit 100 may determine one of a plurality of different detection frequency ranges stored in advance based on at least one of the physical characteristics of the core, the characteristics of the coil, the type of the conductor to be measured, and the manufacturing information of the core.

Here, the plurality of different detection frequency ranges may be stored in the memory (not shown) of the residual current detection device, and the detection frequency ranges of each pulse current determined according to the physical characteristics of the core, the characteristics of the coil, the type of the conductor to be measured, and the manufacturing information of the core may be acquired from results of magnetic saturation characteristic experiments on a plurality of cores having different physical characteristics of the core, characteristics of the coil, the type of the conductor to be measured, and the manufacturing information of the core.

To this end, the control unit 100 may receive various information on the core to which the pulse current is to be applied in the step S700. As an example, the control unit 100 may receive information on the core from a preset input device connected in a wired or wireless manner. Furthermore, one of the plurality of detection frequency ranges may be determined based on at least one of the received core information.

Once the detection frequency range is determined, the control unit 100 may intermittently output a specific voltage at a predetermined time interval according to an initial frequency within the determined detection frequency range to generate a pulse digital signal. Furthermore, the generated pulse digital signal may be applied to the oscillation unit 110 (S702). Then, the oscillation unit 110 may generate a pulse current having a frequency according to the predetermined time interval based on a preset reference frequency in the comparator 113. Furthermore, the generated pulse current may be applied to a coil (e.g., first coil N1) wound on at least one core constituting the core unit 120, for example, at least one DC component detection core. Then, the DC component detection core may be magnetized according to the pulse current.

Meanwhile, when the DC component detection core is magnetized according to the pulse current, a test conductor may be inserted into the core unit 120. In this case, the test conductor may be a conductor through which a preset residual current, for example, a DC residual current, flows. Then, the control unit 100 may detect a residual current for the test conductor inserted into the core unit 120 (S704). Furthermore, a result of detecting the residual current may be output.

In the step S704, when a leakage current for the test conductor is detected, the control unit 100 may change a time interval at which a specific voltage is output according to a frequency change unit generated according to the currently determined detection frequency range. As an example, when the initial frequency is 1.8 KHz, the control unit 100 may output a specific voltage to the oscillation unit 110 every 1/3600 seconds in the step S702 to apply a pulse digital signal having a cycle of 1.8 KHz to the oscillation unit 110. In this state, when the frequency change unit corresponding to the currently determined detection frequency range is 0.1 KHz, the control unit 100 may change a cycle in which a specific voltage is output to the oscillation unit to 1/3400 seconds to apply a pulse digital signal having a cycle of 1.7 KHz to the oscillation unit 110. Therefore, a frequency of the pulse current applied to the coil wound on the core may be changed.

Meanwhile, when a pulse current is applied to the core, the magnetized core has magnetic saturation characteristics such as a hysteresis loop shown in (a) of FIG. 7. That is, when a positive current is applied, the magnetic flux density may increase as the magnetizing force H increases. Conversely, when a negative current is applied while the magnetic flux has a positive value, the magnetic flux may be offset to decrease the magnetic flux density.

However, as shown in (b) of FIG. 7, the core has a characteristic in which the magnetic flux density increases as the magnetizing force H/M increases up to a predetermined level, but enters, when the increased magnetic flux density reaches a maximum magnetic flux density Bm, a state of magnetic saturation and the magnetic flux density no longer increases. As such, the magnetizing force H/M that reaches the maximum magnetic flux density is different for each core because the shape, material, or physical characteristics of the core and the characteristics of the coil are different. Therefore, the magnetizing force H/M that reaches the maximum flux density Bm may be one of the magnetic saturation characteristics of the core.

Accordingly, when an AC current with an inverted polarity is applied to a coil wound on a magnetized core, a magnetic flux of the core may continuously increase until the magnetizing force H according to the magnetic saturation characteristics of the core is reached. However, when the core reaches magnetic saturation due to the increasing magnetization force, the magnetic flux no longer increases and remains at a constant magnitude even when the magnetizing force increases.

However, in the case of the flux gate-type residual current detection device as described above, a residual current may be detected based on a secondary current induced from a magnetic flux generated from the residual current flowing through a conductor to be measured. Therefore, when the core is saturated, a problem may arise in which a residual current flowing in the conductor to be measured is not detected if the magnetic flux of the core does not change. Therefore, the flux gate-type residual current detection device may generate an inverted magnetic flux by applying a pulse current with a periodically inverted polarity to the coil as described above to invert the polarity of the magnetized core at regular intervals, thereby offsetting the magnetic flux of the core.

Therefore, as shown in (a) of FIG. 7, when a positive current is applied, the magnetizing force H may gradually increase depending on a time period for which the positive current is applied. Furthermore, when the polarity of the current applied to the coil is inverted, a magnetic flux having a positive value may be offset while generating a magnetic flux having a negative value. In this case, a maximum value of the magnetic flux density according to the positive current applied to the coil may be +Bm, and a magnetizing force forming the maximum value +Bm of the magnetic flux density according to the positive current of the pulse current may be a maximum magnetization point +Hm according to the positive current.

Meanwhile, as the polarity of the pulse current is inverted, the magnetic flux of the core gradually decreases to reach points b and c. Furthermore, the magnetizing force H may gradually decrease depending on a time period for which the negative current is applied so as to allow the magnetizing force to have a negative value. Furthermore, when the polarity of the current applied to the coil is inverted again, a magnetic flux having a negative value may be offset while generating a magnetic flux having a positive value. In this case, a minimum value of the magnetic flux density according to a negative current applied to the coil may be −Bm, and a magnetizing force forming the maximum value-Bm of the magnetic flux density according to the negative current of the pulse current may be a maximum magnetization point −Hm according to the negative current. Therefore, during one cycle of the frequency of the pulse current having the characteristics of an AC signal, the magnetic flux of the core may pass from point a through points b and c to point d, then through points e and f to reach point a again.

Meanwhile, in the case of a flux gate-type residual current detection device as described above, a residual current may be detected according to a change in magnetic flux. Furthermore, since the magnetic flux varies depending on a magnetization state of the core, the higher the magnetization of the core, the more precise measurement of the residual current may be. In this case, the magnetization of the core may be determined by the magnetizing force, and as shown in (a) of FIG. 7, the smaller the maximum magnetizing force +Hm, −Hm is, the smaller the change in magnetic flux (between point b and point e) may be. Therefore, an amount of change in magnetic flux may be limited, and thus the precision of the residual current detection device may be limited. On the contrary, as the maximum magnetizing force +Hm, −Hm has a larger value, a larger change in magnetic flux (between point b and point e) may be allowed to increase an amount of change in magnetic flux. Therefore, as the magnetizing force increases, the precision of the residual current detection device may increase.

However, as shown above in (b) of FIG. 7, the core has a limit to the magnetic flux that can increase as the magnetizing force increases, and a state in which the magnetic flux density is saturated when the magnetic flux increases to the limit is referred to as a maximum magnetic flux density. Furthermore, when the magnetizing force exceeds a magnetization point corresponding to the maximum magnetic flux density, the magnetic flux does not change due to saturation of the magnetic flux, and thus the detection of the residual current may not be allowed. Therefore, as the maximum magnetic flux density of the core is formed closer to the magnetization point +Hm, −Hm that forms the maximum magnetic flux density value +Bm, −Bm in (a) of FIG. 7, the efficiency and precision of the flux gate-type residual current detection device may increase. That is, a current that generates a magnetizing force that magnetizes the core such that the magnetic flux of the core does not exceed the maximum magnetic flux density but is as close as possible to the maximum magnetic flux density may be a current that matches the magnetic saturation characteristics of the core, optimized for the magnetic saturation characteristics of the core.

However, when the coil to which the pulse current is applied is wound on a core and the current applied to the coil has an AC characteristic in which the polarity is periodically inverted, the current flow applied to the coil may be limited according to an inductive reactance of the coil as in Equation 1 below.

$$I = \frac{V}{{X}_{L}} = \frac{V}{2 π fL} \qquad [ Equation 1 ]$$

Here, I is a current flowing through the coil, X_{L} is an inductive reactance (ohm) of the coil, V is an AC voltage, f is a frequency, and L is an inductance of the coil.

In the Equation 1, V may be a voltage of the pulse current, and f may be a frequency of the pulse current. Furthermore, L is an inductance of the coil, which may be a value included in information on the core, for example, coil information, or determined according to a type of the core, and the like. That is, it may be a preset value.

Therefore, as shown in the Equation 1, an amount of current flowing through the coil wound on the core may be determined according to a frequency of the pulse current applied thereto. Additionally, since a magnetizing force H of the core is directly proportional to a current I flowing through the coil, a magnetizing force of the core may be determined according to a frequency of the pulse current applied to the coil. That is, when the frequency of the pulse current decreases, the magnetizing force H of the core may increase, and the magnetic flux may increase. On the contrary, as the frequency of the pulse current increases, the magnetizing force H of the core may decrease, and the magnetic flux may decrease.

Therefore, a frequency of the pulse current that allows a current to flow so as to generate a magnetizing force that magnetizes the core so that the magnetic flux of the core does not exceed the maximum magnetic flux density but is as close as possible to the maximum magnetic flux density may be a frequency that matches the magnetic saturation characteristics of the core, optimized for the magnetic saturation characteristics of the core.

Meanwhile, as described above, when the core is not magnetically saturated, the magnetization of the core may increase when a current flowing through the coil increases as the frequency of the pulse current decreases. Therefore, even when the residual current flowing through the conductor to be measured is the same, the magnetic flux density may increase according to the increased magnetic flux. On the contrary, when the magnetization of the core forms a maximum magnetic flux density depending on a frequency of the pulse current, that is, when the core is magnetically saturated depending on the frequency of the changed pulse current, it may be difficult to detect a residual current flowing through the conductor to be measured because the magnetic flux density is already in a state of maximum saturation.

Therefore, when the frequency of the pulse current is changed, even if the same residual current flows through the test conductor when the core is not magnetically saturated by the changed frequency of the pulse current, a residual current of the test conductor may be detected normally, or may be different from a residual current detection result detected from the frequency of the pulse current before the change. On the contrary, when the frequency of the pulse current is changed, even if the same residual current flows through the test conductor when the core is magnetically saturated by the changed frequency of the pulse current, a residual current of the test conductor may not be detected normally, or only a residual current detection result that is the same as a residual current detection result detected from the frequency of the pulse current before the change may be output regardless of the change in frequency. That is, when the frequency of the pulse current is changed, it may be possible to detect whether the core has entered a state of magnetic saturation based on a change in the residual current detection result of the control unit 100 for the test conductor according to the frequency of the currently applied pulse current.

Alternatively, the control unit 100 may detect a voltage signal including a pulse current component and a DC component residual current from a secondary current induced in a DC component detection core. Furthermore, depending on whether the detected voltage signal generates a square wave, it may be determined whether the DC component detection core is in a state of magnetic saturation.

As an example, when the core is not saturated, that is, when the core is in a normal state, the detected voltage signal may form a wave shape. However, when the state of the core is in a state of magnetic saturation, the residual current is not detected, so the voltage signal may generate a square wave according to the shape of the pulse current. Accordingly, the control unit 100 may determine whether the DC component detection core is in a magnetic saturation state depending on whether the voltage signal generates a square wave.

In this case, the control unit 100 may detect whether the voltage signal is a square wave based on a change in voltage detected while the polarity is switched from the detected voltage signal. As an example, in the case of a square wave, a voltage change of the voltage signal may not occur above a predetermined level for a predetermined period of time while the polarity is switched. On the contrary, when the core is not saturated, a voltage change may occur above a predetermined level for a predetermined period of time after the polarity is switched. In this manner, when the polarity is switched, the control unit 100 may determine whether the DC component detection core is saturated depending on whether there is a voltage change above a predetermined level for a predetermined period of time.

Therefore, when the frequency of the pulse current is changed according to a frequency change unit in the step S706, the control unit 100 may check whether the core to which the pulse current is applied has reached a state of magnetic saturation based on a residual current detection result of the test conductor (S708).

Furthermore, if it is determined as a result of the check in step S708 that the core has reached a state of magnetic saturation, the control unit 100 may determine a frequency prior to a currently changed frequency of the pulse current as a frequency at which the core can maintain a maximum magnetic flux without being magnetically saturated.

That is, it may be determined by a frequency of the pulse current that matches the magnetic saturation characteristics of the core. Furthermore, the determined pulse current frequency may be stored (S710). Additionally, when the frequency of the pulse current that matches the magnetic saturation characteristics of the core is determined, the test conductor may be removed from the core unit 120.

Meanwhile, when a frequency of a pulse current that matches the characteristics of the core is detected, the control unit 100 may apply a pulse current according to the determined frequency to a coil wound on the core (S712). Accordingly, the control unit 100 may detect a DC component of a residual current flowing through the conductor to be measured inserted through the core unit 120 based on a frequency of the pulse current that matches the magnetic saturation characteristics of the DC component detection core.

Here, the core unit 120 may be configured as a triple core structure. In this case, the DC component detection core may consist of two physically identical cores. Meanwhile, according to the foregoing operation process of FIG. 7, based on a change in a DC component residual current of a test conductor detected by the two cores, it may be possible to detect a frequency of a pulse current that forms a magnetizing force that can maximize an area of a hysteresis loop shown in (a) of FIG. 7 while allowing the cores to have a maximum magnetic flux without being magnetically saturated.

Accordingly, even when the core unit 120 is configured as a triple core structure, the present disclosure may apply a pulse current having an optimized frequency to the cores that detect a DC component residual current according to the magnetic saturation characteristics of the cores that detect the DC component residual current.

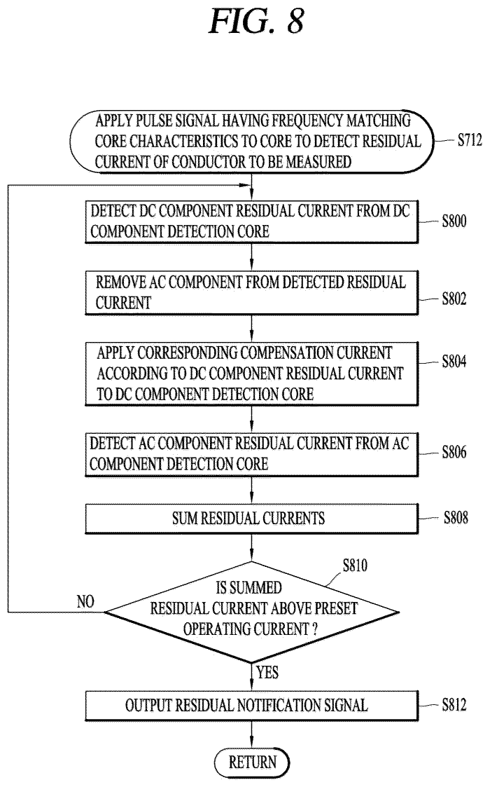

Meanwhile, FIG. 8 is a flowchart showing an operation process of applying a DC component compensation current detected when detecting a residual current of a conductor to be measured other than a test conductor to each core in a residual current detection device according to a first embodiment of the present disclosure.

Referring to FIG. 8, when a pulse current having an optimized frequency that matches the magnetic saturation characteristics of a core (e.g., a DC component detection core) is applied to magnetize the core, the control unit 100 may detect a voltage signal corresponding to a DC component of a residual current based on a secondary current and an intermediary resistance induced from the magnetized core (S800). In this case, the secondary current is induced in the core magnetized by the pulse current, and the voltage signal may include not only a DC component of a residual current component but also the applied pulse current component. Furthermore, the detected voltage signal may be received by the control unit 100.

In order to receive the voltage signal, the control unit 100 may amplify the voltage signal to a level that the control unit 100 can recognize through the amplification unit 101 provided in the control unit 100. Besides, the control unit 100 may remove noise from the voltage signal prior to the amplification through a low-pass filter. Furthermore, the amplified voltage signal may be converted into a digital signal through an ADC.

Meanwhile, the control unit 100 may remove a pulse current component included in the voltage signal through filtering (S802). To this end, the control unit 100 may remove an AC component having a frequency from the voltage signal through a filter (e.g., filter unit 103). In this case, the pulse current has the characteristics of an AC current whose polarity switches periodically, and thus may be removed through the filtering.

Then, the voltage signal may include only a pure DC component of a residual current component detected from the conductor to be measured. Then, the control unit 100 may determine a compensation current corresponding to the DC component of the residual current component. Furthermore, the determined compensation current may be applied to the third coil N3 that applies to the core (S804). In this case, the compensation current may be a DC current having a polarity opposite to that of the DC component of the residual current and having the same magnitude.

Here, the compensation current may be a microscopic level of current that is difficult for the control unit 100 to output. For example, it may be a microscopic level of current that the control unit 100 cannot recognize. In this case, the control unit 100 may control the attenuation unit 102 to apply a microscopic level of the compensation current, and may apply the compensation current attenuated to the microscopic level in the attenuation unit 102 to the third coil N3.

Meanwhile, due to the DC current compensation in the step S804, the magnetic flux due to the DC component residual current of the conductor to be measured may be offset. Then, the control unit 100 may receive a voltage signal corresponding to a secondary current induced in the coil wound on the AC component detection core through the intermediary resistor. In this case, the voltage signal may have noise removed through a low-pass filter, and may be amplified to a level that can be recognized by the control unit 100. Furthermore, it may be converted into a digital signal through the ADC of the control unit 100, and an AC component residual current may be detected based on the voltage signal converted into the digital signal (S806).

Then, the control unit 100 may sum magnitudes of the DC component residual current and the AC component residual current to detect a total amount of residual current of the conductor to be measured. Furthermore, it may be determined whether the total amount of residual current is above a preset operating current (S810).

When the total amount of residual current calculated as a result of the determination in the step S810 is below the preset operating current, the control unit 100 may proceed to step S800 again to perform a process of detecting a DC component leakage current from a DC component core. Furthermore, the following process may be repeated to detect a total amount of residual current detected in the conductor to be measured.

However, when the total amount of residual current calculated as a result of the determination in the step S810 is above the preset operating current, the control unit 100 may start a process related to the occurrence of the residual current (S812).

In the step S812, the control unit 100 may output a control signal, for example, a trip signal, for controlling an interrupter as a residual current above the operating current is detected. Alternately, it may output notification information that notifies the occurrence of a residual current to at least one other system or device related to the residual current. In this case, whether the interrupter is operated may be determined through the other system or device.

Meanwhile, in a residual current detection device according to an embodiment of the present disclosure, when an external magnetic field is formed due to an unexpected overcurrent or the like, the core may enter a state of magnetic saturation due to the influence of the external magnetic field.

Accordingly, the control unit 100 of the residual current detection device according to an embodiment of the present disclosure may demagnetize the core that has fallen into the state of magnetic saturation through reset.

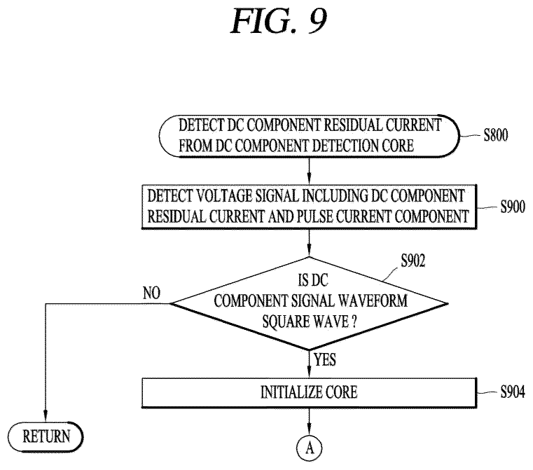

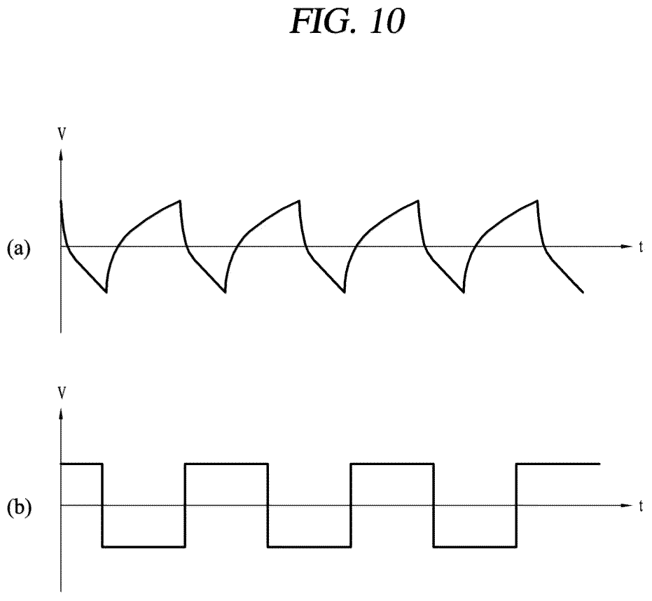

FIG. 9 is a flowchart showing an operation process of initializing a core according to a state of magnetic saturation of a core in a residual current detection device according to a first embodiment of the present disclosure. Furthermore, FIG. 10 is an exemplary diagram showing an output waveform of a DC component detection core according to a state of the core in a residual current detection device according to embodiments of the present disclosure.

First, referring to FIG. 9, when the step S800 of FIG. 8, which detects a DC component residual current, is carried out, the control unit 100 may detect a voltage signal including a pulse current component and a DC component residual current from a secondary current induced to the DC component detection core through an intermediary resistor (S900). Furthermore, it may be possible to determine whether the detected voltage signal generates a square wave (S902).

As an example, when the core is not saturated, that is, when the core is in a normal state, the detected voltage signal may form a wave shape as shown in (a) of FIG. 10. However, when the state of the core is in a state of magnetic saturation, the residual current is not detected, so the voltage signal may generate a square wave according to the shape of the pulse current. Accordingly, the control unit 100 may determine whether the DC component detection core is in a magnetic saturation state depending on whether the voltage signal generates a square wave.

In this case, the control unit 100 may detect a change in voltage detected while the polarity is switched from the detected voltage signal. As an example, as shown in (b) of FIG. 10, in the case of a square wave, the voltage signal may not change above a predetermined level for a predetermined period of time while the polarity is switched.

On the contrary, when the core is not saturated, a voltage change may occur above a predetermined level for a predetermined period of time subsequent to switching the polarity, as shown in (a) of FIG. 10. In this manner, when the polarity is switched, the control unit 100 may determine whether the DC component detection core is saturated in the step S902 depending on whether there is a voltage change above a predetermined level for a predetermined period of time.

Meanwhile, when a result of the determination in the step S902 indicates that the DC component detection core is not magnetically saturated, the control unit 100 may proceed to step S802 in FIG. 8 to continue a process of detecting a residual current of the conductor to be measured.

However, when a result of the determination in the step S902 indicates that the DC component detection core is in a magnetic saturated state, the control unit 100 may initialize the core to demagnetize the core in the magnetic saturated state (S904).

In the step S904, the control unit 100 may amplify the compensation current to a preset magnitude to apply it to the third coil N3 to which the compensation current is applied. In this case, since the DC component detection core cannot be magnetized beyond the maximum magnetic flux density state due to the magnetic saturation characteristics of the core, the preset magnitude may be a magnitude corresponding to a current that forms a magnetizing force that allows the DC component detection core to reach a state of magnetic saturation (e.g., a current magnitude that allows a magnetizing force of +Hm to be generated when the maximum magnetic flux density is +BM in (a) of FIG. 7). Then, the DC component detection core may be demagnetized because the magnetic flux is reduced by the amplified compensation current, that is, the reverse current.

Meanwhile, when core initialization is accomplished through the core demagnetization, the control unit 100 may proceed to step S712 in FIG. 7 to apply a pulse current having a frequency according to the current magnetic saturation characteristics of the core stored in advance to a coil wound on the DC component detection core. Then, according to the operation process shown in FIG. 8, the initialized core may be magnetized again according to a pulse current of a frequency according to its magnetic saturation characteristics, and a residual current of the conductor to be measured may be detected.

Meanwhile, in the foregoing description, a configuration that applies a compensation current or detects a residual current through the core unit 120 has been described, but it may be apparent in the technical field to which the present disclosure pertains that a number of turns of a coil wound on each core or the like may be reflected in the application of the compensation current and the detection of the residual current.

In addition, according to the foregoing description of FIG. 7, the present disclosure may detect a frequency of a pulse current that matches the magnetic saturation characteristics of the core by changing a frequency of a pulse digital signal prior to detecting a residual current from a conductor to be measured.

In addition, a time interval at which the control unit 100 outputs a specific voltage may be changed as described above so as to change a frequency of the pulse digital signal, thereby changing a frequency of a pulse current applied to a coil wound on a DC component detection core without changing a circuit element such as a resistor or capacitor. Accordingly, when a core of a residual current detection device is replaced for reasons such as maintenance or change of use, the replaced core may be magnetized by a pulse current having a frequency that matches the magnetic saturation characteristics of the replaced core without changing an internal configuration of the circuit.

The foregoing present disclosure may be implemented as computer-readable codes on a program-recorded medium. The computer-readable medium includes all kinds of recording devices in which data readable by a computer system is stored. Examples of the computer-readable medium include a hard disk drive (HDD), a solid state disk (SSD), a silicon disk drive (SDD), a ROM, a RAM, a CD-ROM, a magnetic tape, a floppy disk, an optical data storage device and the like, and also include a device implemented in the form of a carrier wave (e.g., transmission over the Internet). Therefore, the detailed description should not be limitedly construed in all of the aspects, and should be understood to be illustrative. The scope of the present disclosure should be determined by reasonable interpretation of the appended claims and all changes that come within the equivalent scope of the present disclosure are included in the scope of the present disclosure.

1. A residual current detection device, the device comprising:
an oscillation unit that generates a pulse current having a preset frequency;
a core unit comprising at least one first core having at least one first coil wound thereon to be magnetized according to the pulse current, a second core having a second coil wound thereon, and a third coil wound on the first core and the second core and to which a compensation current is applied, one end of the first coil being connected to the oscillation unit, one end of the second coil being grounded; and
a control unit that determines a frequency of the pulse current according to at least one of the characteristics of the at least one first core, filters out a component having a frequency from a voltage signal of a current induced in the at least one first core to detect a DC component leakage current of a conductor to be measured, and applies a reverse current corresponding to the detected DC component leakage current to the third coil as the compensation current.

2. The device of claim 1, wherein the characteristics of the at least one first core are at least one of a shape or thickness of the core, a diameter or material of the core, a diameter of a hollow inside the core, a material or number of turns of a coil wound on the core, a spacing between turns of the coil, a manufacturer and manufacturing number of the core, and a type of the conductor to be measured.

3. The device of claim 2, further comprising:
a memory in which a plurality of detection frequencies are stored according to respective different characteristics of the at least one first core,
wherein the control unit determines one of the plurality of detection frequencies as a frequency of the pulse current based on the characteristics of the at least one first core.

4. The device of claim 3, wherein the control unit changes, when the DC component leakage current of the conductor to be measured is detected according to one of the plurality of detection frequencies, the frequency of the pulse current to another one of the plurality of detection frequencies, detects again the DC component leakage current of the conductor to be measured according to the changed frequency of the pulse current, and determines whether the at least one first core is magnetically saturated to detect a frequency of a pulse current according to a magnetic saturation characteristic of the at least one first core.

5. The device of claim 4, wherein the control unit determines whether the magnetic saturation of the at least one first core is achieved based on whether a voltage signal detected from the at least one first core generates a square wave.

6. The device of claim 5, wherein the control unit determines, when a polarity of the voltage signal detected from the at least one first core is switched, whether the voltage signal detected from the at least one first core generates a square wave based on whether there is a voltage change above a predetermined level for a predetermined period of time.

7. The device of claim 4, wherein the control unit determines, when a magnetic saturation frequency of a pulse current that magnetically saturates the at least one first core is detected, a frequency close to the magnetic saturation frequency from among frequencies of pulse currents that do not magnetically saturate the at least one first core as a pulse current frequency according to the magnetic saturation characteristics of the at least one first core.

8. The device of claim 4, wherein the conductor to be measured is a test conductor through which a preset magnitude of a DC component of a residual current and an AC component of a residual current flow.

9. The device of claim 1, wherein the oscillation unit receives a pulse digital signal in which a state of outputting a specific voltage and a state of not outputting voltage are repeated at a preset time cycle, and generates the pulse current in which a positive current and a negative current alternate at the preset time cycle in synchronization with the pulse digital signal, and
wherein the control unit applies a pulse digital signal that is repeated at the preset time cycle to the oscillation unit based on the frequency of the pulse current determined according to the characteristics of the at least one first core.

10. The device of claim 9, wherein the oscillation unit has a comparator having a preset reference voltage, and
wherein the comparator outputs, when a pulse digital signal having a voltage higher than the reference voltage is input, a current having a preset magnitude of a positive voltage, and outputs, when a pulse digital signal having a voltage lower than the reference voltage is input, a current having a preset magnitude of a negative voltage.

11. The device of claim 10, wherein the reference voltage has a magnitude of half of the specific voltage, and
wherein the preset magnitude of positive and negative voltages are positive and negative voltages corresponding to the reference voltage.

12. A residual current detection device, the device comprising:
an oscillation unit that generates a pulse current having a preset frequency;
a core unit comprising at least one first core having at least one first coil wound thereon to be magnetized according to the pulse current, a second core having a second coil wound thereon, and a third coil wound on the first core and the second core and to which a compensation current is applied, one end of the first coil being connected to the oscillation unit, one end of the second coil being grounded;
a residual current detection unit connected to the other end of the at least one first core and the other end of the second core to sum a voltage signal detected from the first core and a voltage signal detected from the second core;
an amplification unit that inverts and amplifies a voltage signal according to a voltage signal summation result of the residual current detection unit to generate a compensation current applied to the third coil; and
a control unit that determines a frequency of the pulse current according to at least one of the characteristics of the at least one first core, and detects a DC component leakage current flowing through the conductor to be measured based on the compensation current.

13. The device of claim 12, wherein the residual current detection unit comprises a differential amplifier having a non-inverting input terminal connected to the other end of the second coil and an inverting input terminal connected to the other end of the first coil to sum a voltage signal corresponding to a DC component residual current of the conductor to be measured and a voltage signal corresponding to an AC component residual current thereof, and
wherein the differential amplifier is connected to the non-inverting input terminal via a resistor and capacitor whose output terminal acts as a noise filter so as to allow an output of the differential amplifier to be fed back to the non-inverting input terminal.

14. The device of claim 13, wherein the amplification unit comprises an operational amplifier having a first input terminal connected to a ground and a second input terminal connected to the output terminal of the differential amplifier via a preset magnitude of a first resistor, and
wherein the output terminal of the operational amplifier is connected to the second input terminal via a preset magnitude of a second resistor, and connected to the non-inverting input terminal of the differential amplifier so as to allow an output of the operational amplifier to be fed back to the differential amplifier.

15. The device of claim 12, wherein the at least one first core comprises:
a first-first core having a first-first coil wound thereon to which the pulse current is applied;
an inverting amplifier that inverts a polarity of the pulse current;
a first-second core having a first-second coil wound thereon to which a pulse current having its polarity inverted by the inverting amplifier is applied; and
an adding amplifier that synthesizes voltage signals respectively corresponding to secondary currents induced in the first-first coil and the first-second coil.

16. The device of claim 12, further comprising:
a memory in which a plurality of detection frequencies are stored according to respective different characteristics of the at least one first core,
wherein the control unit determines one of the plurality of detection frequencies as a frequency of the pulse current based on the characteristics of the at least one first core.

17. The device of claim 16, wherein the control unit changes, when the DC component leakage current of the conductor to be measured is detected according to one of the plurality of detection frequencies, the frequency of the pulse current to another one of the plurality of detection frequencies, detects again the DC component leakage current of the conductor to be measured according to the changed frequency of the pulse current, and determines whether the at least one first core is magnetically saturated to detect a frequency of a pulse current according to a magnetic saturation characteristic of the at least one first core.

18. The device of claim 17, wherein the control unit determines, when a magnetic saturation frequency of a pulse current that magnetically saturates the at least one first core is detected, a frequency close to the magnetic saturation frequency from among frequencies of pulse currents that do not magnetically saturate the at least one first core as a pulse current frequency according to the magnetic saturation characteristics of the at least one first core.
